(19) United States
(12) Patent Application Publication
(10) Pub. No.: US 2011/0148447 A1
(43) Pub. Date: Jun. 23, 2011

(54) MULTILAYER CERAMIC SUBSTRATE AND PROBE BOARD USING PILLAR-TYPE CONDUCTOR AND FABRICATING METHODS OF THE SAME

(75) Inventors: Won Hee YOO, Suwon (KR); Byeung Gyu Chang, Suwon (KR); Yong Suk Kim, Yongin (KR)

(73) Assignee: SAMSUNG ELECTRO-MECHANICS CO., LTD.

(21) Appl. No.: 12/836,955

(22) Filed: Jul. 15, 2010

(30) Foreign Application Priority Data
Dec. 22, 2009 (KR) 10-2009-0129301

(51) Int. Cl. G01R 1/067; C04B 35/74; H05K 1/11

(52) U.S. Cl. 324/755.01; 264/614; 174/266

(57) ABSTRACT

There are provided a multilayer ceramic substrate and a probe board formed using a pillar-type conductor formed by including preparing a ceramic sheet having at least one through hole; filling the inside of the through hole with a conductive material; firing the ceramic sheet so that the conductive material is fired to form a pillar-type conductor; and removing the ceramic sheet so that the pillar-type conductor remains, and fabricating methods of the same. The multilayer ceramic substrate and the probe board use the pillar-type conductor that can fill the unfilled region formed within the ceramic sintered body, such that the electrical characteristics and surface flatness thereof are improved. In addition, the multilayer ceramic substrate and the probe board formed by using the pillar-type conductor with the improved adhesion and electrical characteristics between the ceramic sintered body and the connecting pad, and the fabricating methods of the same are provided.

### CROSS-REFERENCE TO RELATED APPLICATIONS

This application claims the priority of Korean Patent Application No. 10-2009-0129301 filed on Dec. 22, 2009, in the Korean Intellectual Property Office, the disclosure of which is incorporated herein by reference.

### BACKGROUND OF THE INVENTION

1. Field of the Invention

The present invention relates to a multilayer ceramic substrate and a probe board using a pillar-type conductor, and more particularly, to a multilayer ceramic substrate and a probe board in which electrical characteristics and surface flatness are improved by using a pillar-type conductor that can fill an unfilled region of a via formed within a ceramic sintered body, and fabricating methods of the same.

2. Description of the Related Art

A general semiconductor test apparatus includes a tester, a performance board, a probe card, a chuck, and a prober to test the electrical characteristics of chips fabricated on a wafer. The probe card of the semiconductor test apparatus also serves to receive signals generated from the tester through the performance board to transfer them to the pads of the chip within the wafer and transfer the signals output from the pads of the chip to the tester through the performance board.

The probe card used in the semiconductor test apparatus generally uses a multilayer ceramic substrate such as a Low Temperature Co-fired Ceramic (LTCC) substrate and a High Temperature Co-fired Ceramic (HTCC) substrate. In order to fabricate the multilayer ceramic substrate integrated as above, it is required that a three-dimensional circuit is able to be implemented and a plurality of inner interlayer conduction vias and circuit pattern structures are provided.

A pattern for forming a probe fin is formed on one surface of the multilayer ceramic substrate for the probe card, and a pattern for joining a Printed Circuit Board (PCB) or an interposer is formed on the other surface thereof.

In order to implement the stable electrical characteristics of the multilayer ceramic substrate, the electrical connection and adhesion between a pattern and a via should be secured. In particular, in the case of a multilayer ceramic substrate having a large area and a thick thickness, the interlayer height is high so that an internal electrode is not sufficiently filled in the portion where the pattern contacts the via or defects occur in the connection due to the difference of contraction temperature or the infiltration of etching solution, thereby causing the degradation of adhesion, disconnection defects or the degradation of electrical characteristics.

### SUMMARY OF THE INVENTION

An object of the present invention provides a multilayer ceramic substrate and a probe board of which electrical characteristics and surface flatness are improved by using a pillar-type conductor that can fill an unfilled region of a via formed within a ceramic sintered body, and fabricating methods of the same.

According to an aspect of the present invention, there is provided a method of fabricating a pillar-type conductor, including: preparing a ceramic sheet having at least one through hole; filling the inside of the through hole with a conductive material; firing the ceramic sheet so that the conductive material is fired to forma pillar-type conductor; and removing the ceramic sheet so that the pillar-type conductor remains.

Herein, the ceramic sheet may be formed by stacking a plurality of ceramic green sheets so that the height of the pillar-type conductor is controlled.

According to another aspect of the present invention, there is provided a method of fabricating a multilayer ceramic laminate, including: preparing a ceramic laminate by stacking a plurality of ceramic green sheets including a via through which a conductive material is filled in at least one first through hole; forming a surface sheet having a buffering electrode connected to the via and provided on the wall surface of a second through hole on the via; inserting a pillar-type conductor into the second through hole so that one surface thereof is exposed; and forming a ceramic sintered body by firing the ceramic laminate.

Herein, the surface sheet may be formed by stacking a plurality of ceramic green sheets.

Further, after the forming of the ceramic sintered body, the method may further include grinding the surface of the ceramic sintered body.

According to another aspect of the present invention, there is provided a method of fabricating a probe board, including: preparing a ceramic laminate by stacking a plurality of ceramic green sheets including a via through which a conductive material is filled in at least one first through hole; forming a surface sheet having a buffering electrode connected to the via and provided on the wall surface of a second through hole on the via; inserting a pillar-type conductor into the second through hole so that one surface thereof is exposed; forming a ceramic sintered body by firing the ceramic laminate; forming a connection pad on the ceramic laminate; and joining a probe part made of conductive material on the ceramic laminate.

Herein, the surface sheet may be formed by stacking a plurality of ceramic green sheets.

Further, after the forming of the ceramic sintered body, the method may further include grinding the surface of the ceramic sintered body.

Further, after the grinding of the ceramic sintered body, the method may further include stacking a protecting layer on the ceramic sintered body.

The connection pad may be formed by forming at least one barrier ribs arranged on the protecting layer at a predetermined interval and filling the inside of the barrier ribs with a metal.

Meanwhile, the connection pad may be formed by an electroless plating method.

Further, before forming the barrier ribs, a plating seed layer may be formed on the protecting layer.

Herein, the connection pad may be formed by an electroplating method.

The probe part may be joined by interposing a solder between the plating seed layer and the probe part and removing the protecting layer and the plating seed layer formed on an adhesive pad by melting the solder.

According to another aspect of the present invention, there is provided a multilayer ceramic substrate, including: a ceramic laminate formed by stacking a plurality of ceramic green sheets including a via through which a conductive material is filled in at least one first through hole; a surface sheet provided on the via and having a buffering electrode connected to the via and provided on the wall surface of a second through hole; and a pillar-type conductor inserted into the second through hole so that one surface thereof is exposed.

Herein, the surface sheet may be formed by stacking a plurality of ceramic green sheets.

According to another aspect of the present invention, there is provided a probe board, including: a ceramic laminate formed by stacking a plurality of ceramic green sheets including a via through which a conductive material is filled in at least one first through hole; a surface sheet provided on the via and having a buffering electrode connected to the via and provided on the wall surface of a second through hole; a pillar-type conductor inserted into the second through hole so that one surface thereof is exposed; a ceramic sintered body formed by firing the ceramic laminate; a connection pad formed on the ceramic sintered body; and a probe part joined to the ceramic sintered body and made of a conductive material.

Herein, the surface sheet may be formed by stacking a plurality of ceramic green sheets.

Further, the method may further include a protecting layer on the ceramic sintered body.

Meanwhile, the connection pad may be formed by an electroless plating method.

Further, the connection pad may be formed by an electroplating method.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A through 1D are schematic cross-sectional views showing a fabricating process of a pillar-type conductor according to an exemplary embodiment of the present invention;

FIGS. 2A through 2D are schematic cross-sectional views showing a fabricating process of a pillar-type conductor according to another exemplary embodiment of the present invention;

FIGS. 3A through 3D are schematic cross-sectional views showing a fabricating process of a multilayer ceramic substrate using a pillar-type conductor according to an exemplary embodiment of the present invention;

FIGS. 4A through 4D are schematic cross-sectional views showing a fabricating process of a multilayer ceramic substrate using a pillar-type conductor according to an exemplary embodiment of the present invention;

FIGS. 5A through 5I are schematic cross-sectional views showing a fabricating process of a probe board using a pillar-type conductor according to an exemplary embodiment of the present invention; and

FIGS. 6A and 6B are optical photographs showing a ceramic substrate fabricated according to exemplary embodiments of the present invention and a ceramic substrate according to the prior art as seen from the top.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the concept of the invention to those skilled in the art. In the drawings, the shapes and dimensions may be exaggerated for clarity, and the same reference numerals will be used throughout to designate the same or like components.

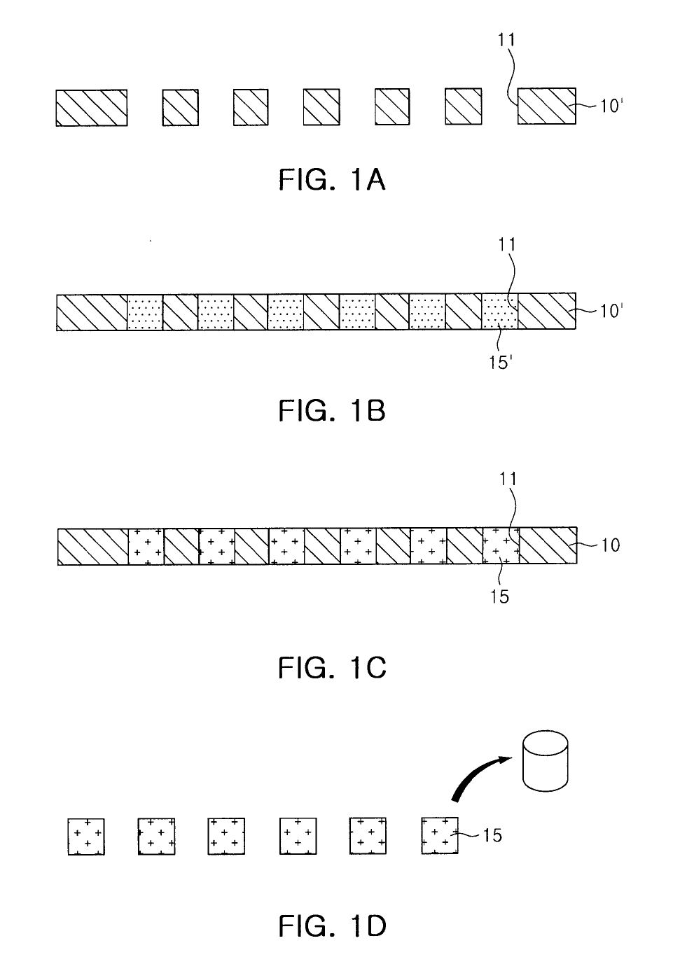

Hereinafter, a fabricating process of a pillar-type conductor according to an exemplary embodiment of the present invention will now be described with reference to FIGS. 1A through 1D.

FIGS. 1A through 1D are schematic cross-sectional views showing a fabricating process of a pillar-type conductor according to an exemplary embodiment of the present invention.

As shown in FIG. 1A, a ceramic sheet 10′ having at least one through hole 11 is provided.

Then, as shown in FIG. 1B, when the ceramic sheet 10′ is fired after filling the inside of the through hole 11 with a conductive material 15′, the conductive material 15′ inside the through hole 11 is also co-fired, such that a pillar-type conductor 15 is formed inside the through hole 11 of the fired ceramic sheet 10 as shown in FIG. 10.

Then, as shown in FIG. 1D, the pillar-type conductor 15 is completed by removing the fired ceramic sheet 10. Herein, although the pillar-type conductor 15 may have a cylindrical shape as shown in the drawing, the shape of the pillar-type conductor 15 is not limited thereto but it may be varied according to the shape of a via into which the pillar-type conductor 15 is inserted.

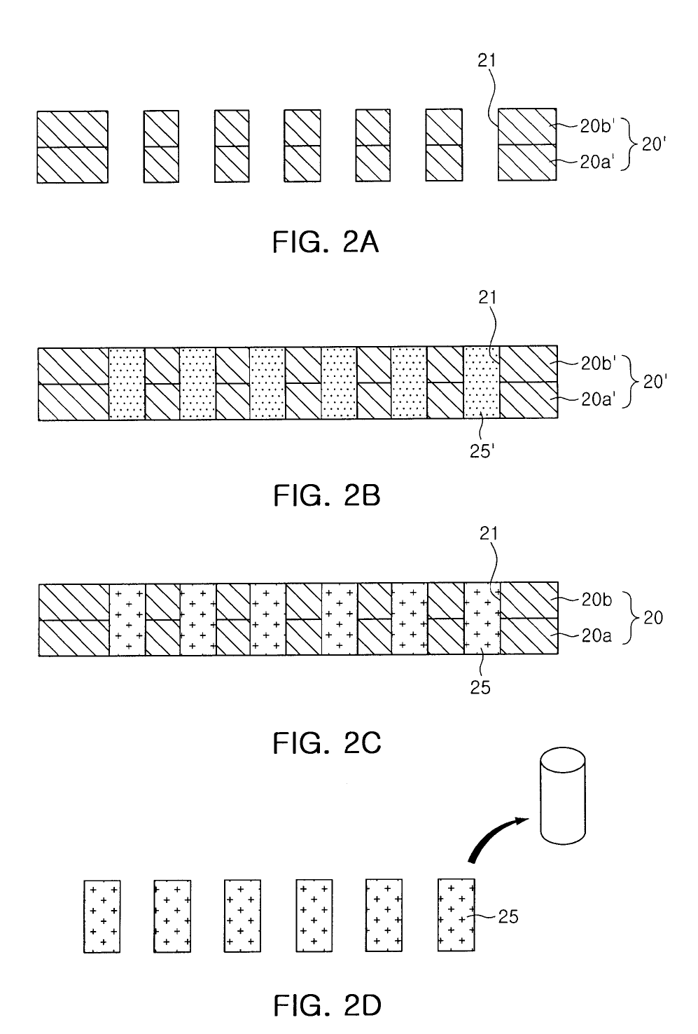

Hereinafter, a fabricating process of a pillar-type conductor according to another exemplary embodiment of the present invention will now be described with reference to FIGS. 2A through 2D.

FIGS. 2A through 2D are schematic cross-sectional views showing a fabricating process of a pillar-type conductor according to another exemplary embodiment of the present invention.

As shown in FIG. 2A, a ceramic sheet 20′ having at least one through hole 21 is provided. Herein, the ceramic sheet 20′ is formed by stacking a plurality of ceramic green sheets 20a′ and 20b′ so that the height of a conductive material 25′ to be filled is controlled.

Then, when the ceramic sheet 20′ is fired after filling the inside of the through hole 21 with the conductive material 25′ , the conductive material 25′ inside the through hole 21 is also co-fired, such that a pillar-type conductor 25 is formed inside the through hole 21 of the fired ceramic sheet 20 as shown in FIG. 2C.

Then, as shown in FIG. 2D, the pillar-type conductor 25 is completed by removing the fired ceramic sheet 20. Herein, although the pillar-type conductor 25 may have a cylindrical shape as shown in the drawing, the shape of the pillar-type conductor 25 is not limited thereto but it may be varied according to the shape of a via into which the pillar-type conductor 25 is inserted.

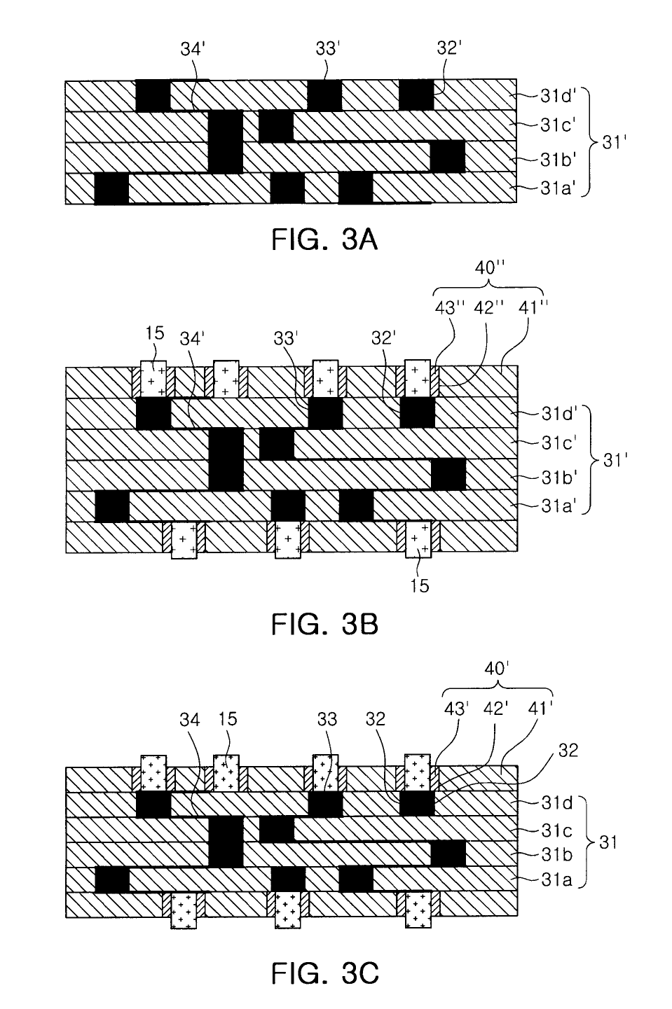

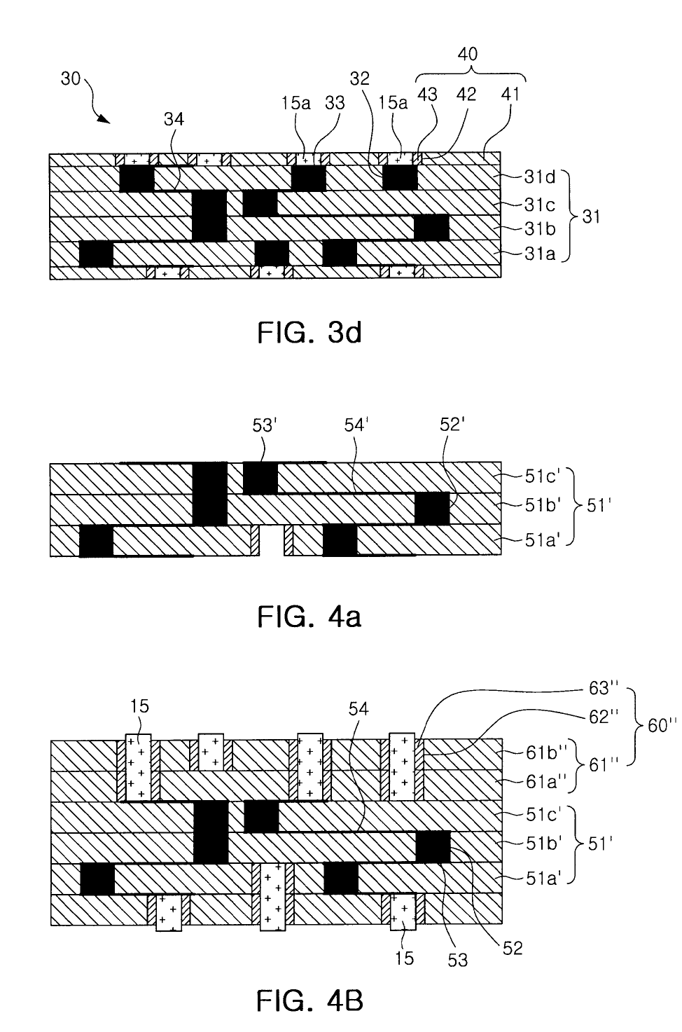

Hereinafter, a fabricating process of a pillar-type conductor according to an exemplary embodiment of the present invention will now be described with reference to FIGS. 3A through 3D.

FIGS. 3A through 3D are schematic cross-sectional views showing a fabricating process of a multilayer ceramic substrate using a pillar-type conductor according to an exemplary embodiment of the present invention.

As shown in FIG. 3A, a ceramic laminate 31′ is provided by stacking a plurality of ceramic green sheets 31a′, 31b′, 31c′ and 31d′ that include a via 33′ through which a conductive material is filled in at least one first through hole 32′.

Then, as shown in FIG. 3B, after a surface sheet 40″, that is a ceramic sheet 41″, having a buffering electrode 43″ connected to the via 33′ and provided on the wall surface of a second through hole 42″ is formed on the via 33′ a pillar-type conductor 15 is inserted into the second through hole 42″ so that one surface of the pillar-type conductor 15 is exposed.

Then, as shown in FIG. 3c, a ceramic sintered body 31 is formed by firing the ceramic laminate 31′ in the previous process. Herein, the ceramic sintered body 31 is contracted in a thickness direction by being subject to the firing process; however, the pillar-type conductor 15, which has been already fired, is not contracted. Therefore, as shown in the drawing, the pillar-type conductor 15 has a shape in which a predetermined portion thereof is projected to the outside of the ceramic sintered body 31.

Therefore, as shown in FIG. 3D, after forming of the ceramic sintered body 31, a process of grinding the surface of the ceramic sintered body 31 may further be performed. After the process of grinding, the surface sheet 40 includes the second through hole 42, the buffering electrode 43, the pillar-type conductor 15a contacting the buffering electrode 43, and the ceramic sheet 41, each having a reduced size.

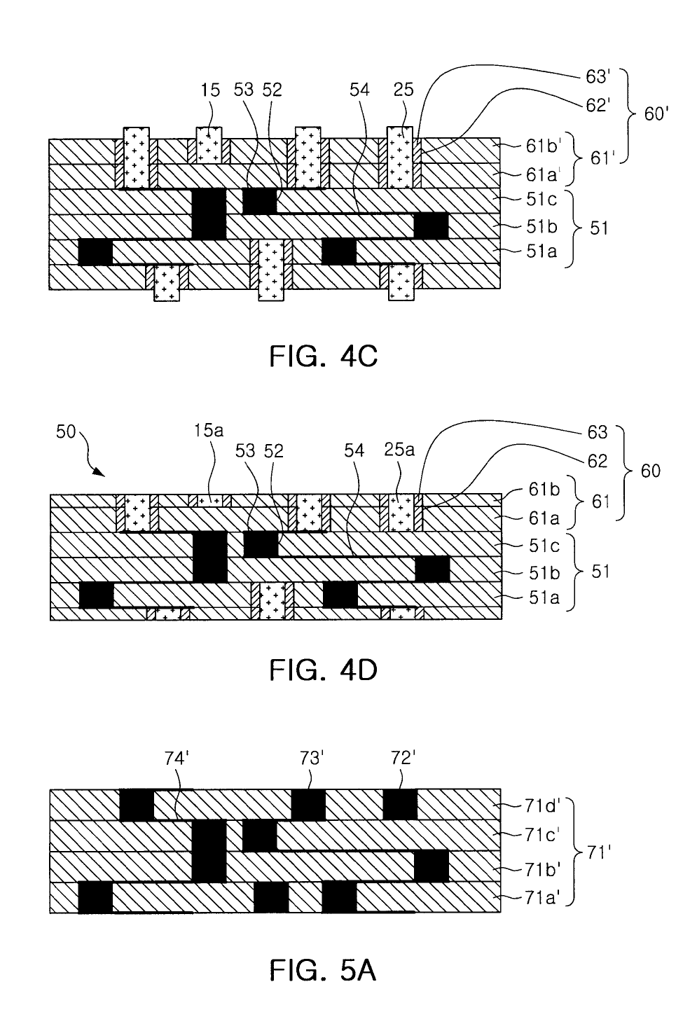

Hereinafter, a fabricating process of a multilayer ceramic substrate using a pillar-type conductor according to another exemplary embodiment of the present invention will now be described with reference to FIGS. 4A through 4D.

FIGS. 4A through 4D are schematic cross-sectional views showing a fabricating process of a multilayer ceramic substrate using a pillar-type conductor according to an exemplary embodiment of the present invention.

As shown in FIG. 4A, a ceramic laminate 51′ is provided by stacking a plurality of ceramic green sheets 51a′, 51b′, and 51c′ that include a via 53′ through which a conductive material is filled in at least one first through hole 52′.

Then, as shown in FIG. 4B, after a surface sheet 60″, that is a ceramic sheet 61″, having a buffering electrode 63″ connected to the via 53′ and provided on the wall surface of a second through hole 62″ is formed on the via 53′, pillar-type conductors 15 and 25 are inserted into the second through hole 62″ so that surface of the pillar-type conductors 15 and 25 having different lengths depending on the length of the second through hole 62″ are exposed. Herein, the ceramic sheet 61″ is formed by stacking a plurality of ceramic green sheets 61a″ and 60b″.

Then, as shown in FIG. 4C, a ceramic sintered body 51 is formed by firing the ceramic laminate 51′ in the previous process. Herein, the ceramic sintered body 51 is contracted in a thickness direction by being subject to the firing process, but the pillar-type conductors 15 and 25, which have been already fired, are not contracted. Therefore, as shown in the drawing, the pillar-type conductors 15 and 25 have a shape in which a predetermined portion thereof is projected to the outside of the ceramic sintered body 51.

Therefore, as shown in FIG. 4D, after the forming of the ceramic sintered body 51, a process of grinding the surface of the ceramic sintered body 51 may further be performed. After the process of grinding, the surface sheet 60 includes the second through hole 62, the buffering electrode 63, the pillar-type conductors 15a and 25a contacting the buffering electrode 63, and the ceramic sheet 61, each having reduced size.

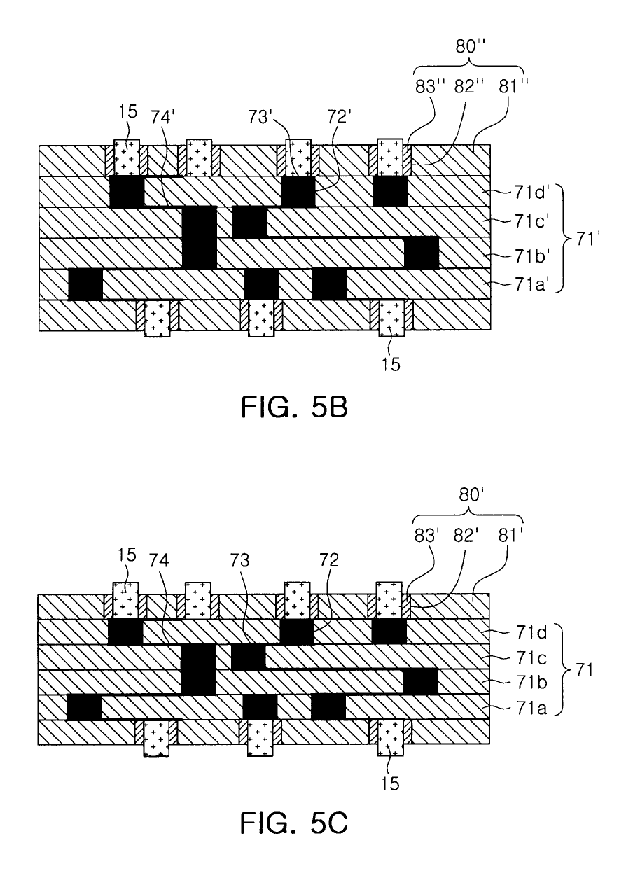

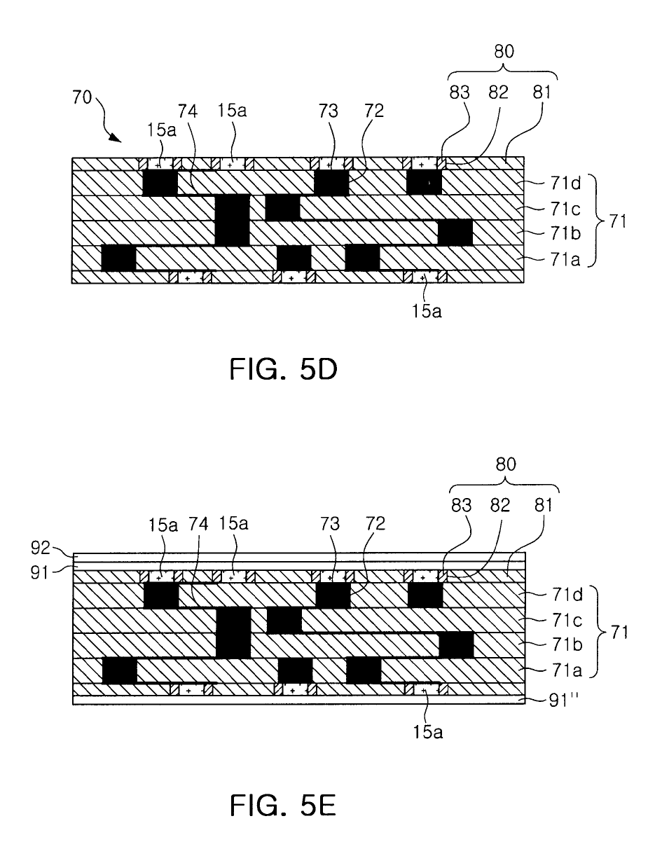

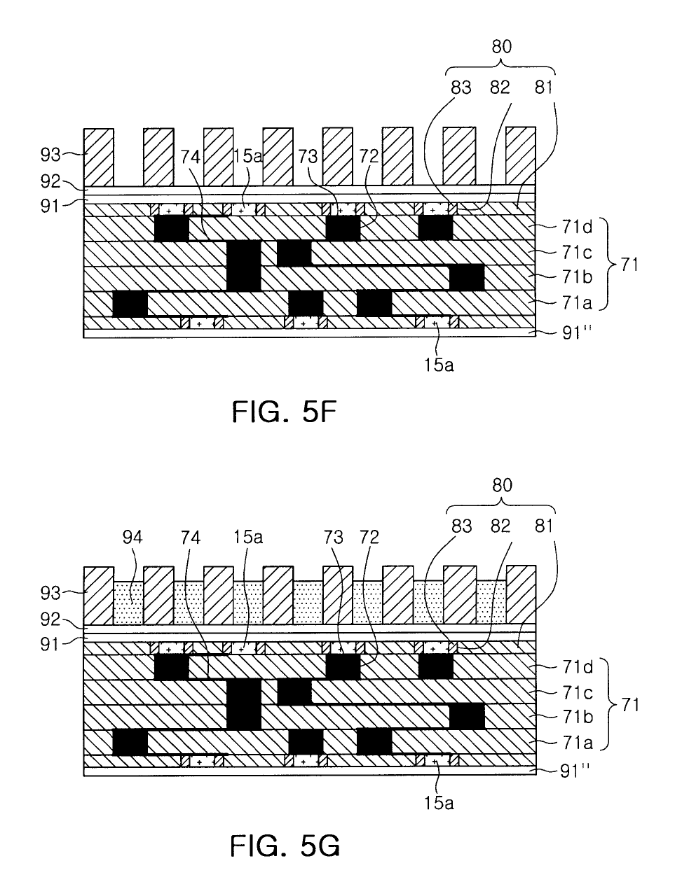

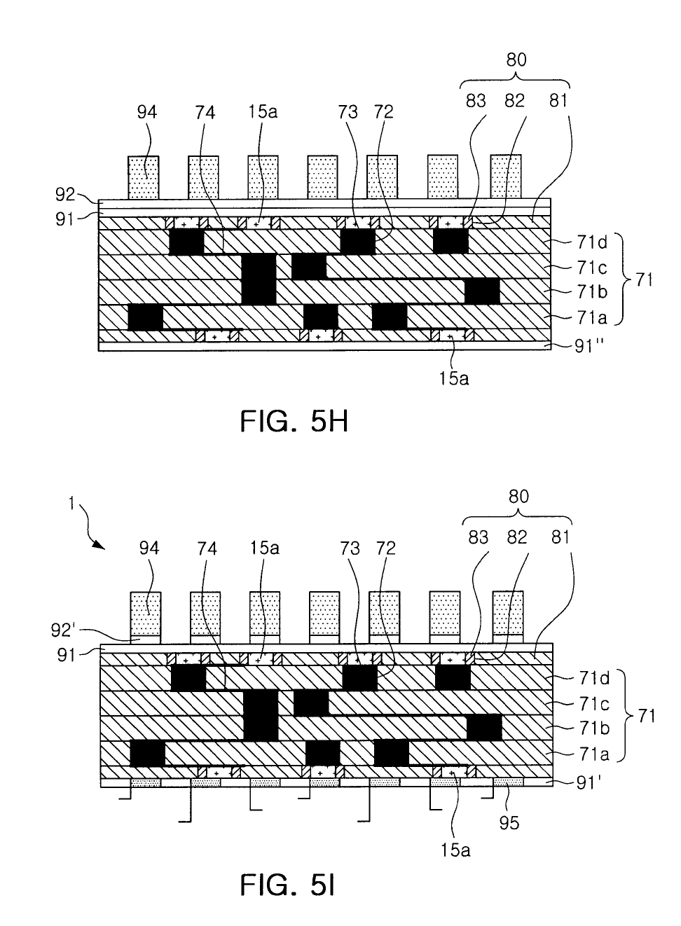

Hereinafter, a fabricating process of a probe board using a pillar-type conductor according to an exemplary embodiment of the present invention will now be described with reference to FIGS. 5A through 51.

FIGS. 5A through 51 are schematic cross-sectional views showing a fabricating process of a probe board using a pillar-type conductor according to an exemplary embodiment of the present invention.

As shown in FIG. 5A, a ceramic laminate 71′ is provided by stacking a plurality of ceramic green sheets 71a′, 71b′, 71c′ and 71d′ that include a via 73′ through which a conductive material is filled in at least one first through hole 72′.

Then, as shown in FIG. 5B, after a surface sheet 80″, that is a ceramic sheet 81″, having a buffering electrode 83″ connected to the via 73′ and provided on the wall surface of a second through hole 82″ is formed on the via 73′, a pillar-type conductor 15 is inserted into the second through hole 82″ so that one surface of the pillar-type conductor 15 is exposed.

Then, as shown in FIG. 5C, a ceramic sintered body 71 is formed by firing the ceramic laminate 71′ in the previous process. Herein, the ceramic sintered body 71 is contracted in a thickness direction by being subject to the firing process, but the pillar-type conductor 15, which has been already fired, is not contracted. Therefore, as shown in the drawing, the pillar-type conductor 15 has a shape in which a predetermined portion thereof is projected to the outside of the ceramic sintered body 71.

Therefore, as shown in FIG. 5D, after forming of the ceramic sintered body 71, a process of grinding the surface of the ceramic sintered body 71 may further be performed. After the process of grinding, the surface sheet 80 includes the second through hole 82, the buffering electrode 83, the pillar-type conductor 15a contacting the buffering electrode 83, and the ceramic sheet 81, each having reduced size.

Then, as shown in FIG. 5E, protecting layers 91 and 91″ are formed in order to cover at least one surface of an upper surface or a lower surface of the ceramic sintered body 71. The protecting layers 91 and 91″ are used in order to protect the ceramic sintered body 71 from a strong acid or a strong base used in joining a probe part 95 (see FIG. 51) . To this end, the protecting layers 91 and 91″ may be made of a ceramic material, and may also be made of a polymer material such as Teflon, fiber reinforced plastic, polyvinyl chloride, urethane, and the like, but the material constituting the protecting layers 91 and 91″ is not limited thereto.

Then, as shown in FIG. 5F, a plating seed layer 92 is formed on the ceramic laminate 71 on which the protecting layers 91 and 91″ are formed. The plating seed layer 92 may be formed on the ceramic laminate 71 on which a connection pad 94 (see FIG. 5G) is to subsequently be formed.

Meanwhile, the plating seed layer 92 is necessary when an electroplating method is used and thus, it may not be formed when an electroless plating method is used.

Then, as shown in FIG. 5G, after a photoresist (not shown) is applied on the plating seed layer 92, exposure, development and etching are performed thereupon, thereby forming a barrier rib for plating 93.

Then, as shown in FIG. 5H, a connection pad 94 may be formed by filling a metallic material between the barrier ribs for plating 93, and as shown in FIG. 51, the connection pad 94 may be formed by removing the barrier rib for plating 93. Herein, the connection pad 94 may be formed by an electro plating method and alternatively, may also be formed by an electroless plating method as described above. Thereafter, although not shown, a component such as a printed circuit board may be connected to the connection pad 94.

Then, as shown in FIG. 51, unnecessary portions of the plating seed layer 92 can be removed by performing an etching process using the connection pad 94 as a mask, and the probe part 95 is finally joined to one surface of the ceramic laminate 71, thereby making it possible to complete a probe board 1.

Herein, after a solder is interposed between the protecting layer 91″ and the probe part 95, the protecting layer 91′, of which a portion is removed, is formed by melting the solder, thereby making it possible to join the probe part 95. When the plating seed layer 92 is further formed on the protecting layer 91″, the solder is interposed between the plating seed layer 92 and the probe part 95 and then the protecting layer 91″ and the plating seed layer 92 are removed by melting the solder, thereby making it possible to join the probe part 95.

The multilayer ceramic substrate 30 fabricated according to exemplary embodiments of the present invention may be configured to include a ceramic laminate 31 formed by stacking a plurality of ceramic green sheets 31a, 31b, 31c, and 31d including a via 33 through which a conductive material is filled in at least one first through hole 32, a surface sheet 40 that is provided on the via 33 and has a buffering electrode 43 connected to the via 33 and provided on the wall surface of a second through hole 42, and a pillar-type conductor 15a that is inserted into the second through hole 42 so that one surface thereof is exposed.

Further, the probe board 1 fabricated according to exemplary embodiments of the present invention may be configured to include a ceramic laminate 71′ formed by stacking a plurality of ceramic green sheets 71a, 71b, 71c, and 71d including a via 73 through which a conductive material is filled in at least one first through hole 72, a surface sheet 80 that is provided on the via 73 and has a buffering electrode 83 connected to the via 73 and provided on the wall surface of a second through hole 82, a pillar-type conductor 15a inserted into the second through hole 82 so that one surface thereof is exposed; a ceramic sintered body 71 formed by firing the ceramic laminate 71′, a connection pad 94 formed on the ceramic sintered body 71; and a probe part 95 joined to the ceramic sintered body 71 and made of the conductive material.

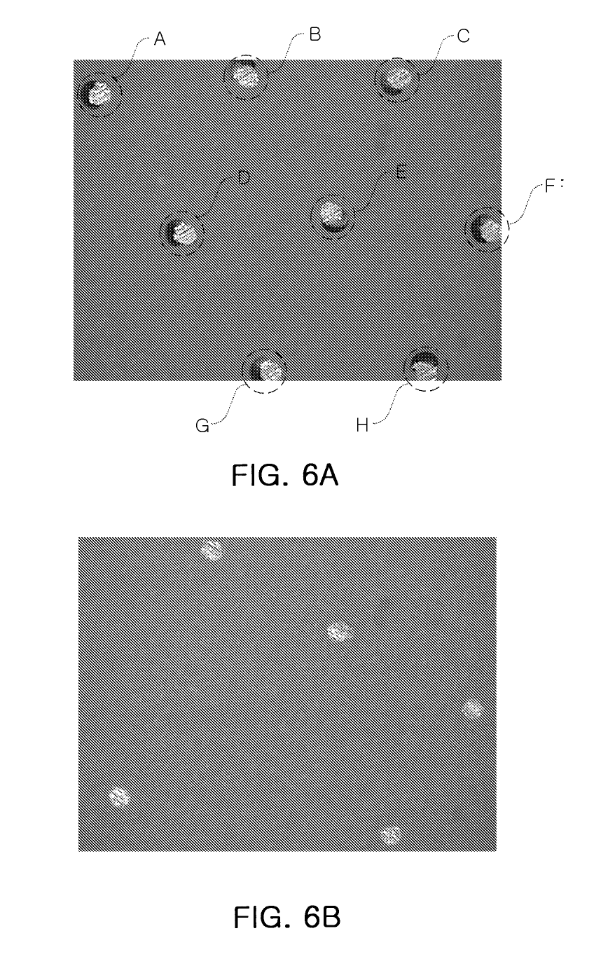

The photographs of the multilayer ceramic substrate fabricated according to exemplary embodiments of the present invention and a multilayer ceramic substrate according to the prior art as seen from the top will now be described with reference to FIGS. 6A and 6B.

Referring to FIG. 6A, it can be appreciated that empty spaces are formed in vias as shown in portions A to H marked using a red circle in the photograph of the ceramic substrate according to the prior art as seen from the top.

On the other hand, referring to FIG. 6B, it can be appreciated that empty spaces are not formed in the pillar-type conductor 15 but a flat surface is formed thereon in the photograph of the ceramic substrate 30 fabricated according to exemplary embodiments of the present invention as seen from the top.

As set forth above, according to exemplary embodiments of the present invention, the multilayer ceramic substrate and the probe board use the pillar-type conductor that can fill the unfilled region of vias formed within the ceramic sintered body, such that the electrical characteristics and surface flatness thereof are improved. In addition, the multilayer ceramic substrate and the probe board formed by using the pillar-type conductor with the improved adhesion and electrical characteristics between the ceramic sintered body and the connection pad are provided and the fabricating methods of the same are provided.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of fabricating a pillar-type conductor, comprising:
preparing a ceramic sheet having at least one through hole;
filling the inside of the through hole with a conductive material;
firing the ceramic sheet so that the conductive material is fired to form a pillar-type conductor; and
removing the ceramic sheet so that the pillar-type conductor remains.

2. The method of fabricating the pillar-type conductor of claim 1, wherein the ceramic sheet is formed by stacking a plurality of ceramic green sheets so that the height of the pillar-type conductor is controlled.

3. A method of fabricating a multilayer ceramic laminate, comprising:
preparing a ceramic laminate by stacking a plurality of ceramic green sheets including a via through which a conductive material is filled in at least one first through hole;
forming a surface sheet having a buffering electrode connected to the via and provided on the wall surface of a second through hole on the via;
inserting a pillar-type conductor into the second through hole so that one surface thereof is exposed; and
forming a ceramic sintered body by firing the ceramic laminate.

4. The method of fabricating the multilayer ceramic laminate of claim 1, wherein the surface sheet is formed by stacking a plurality of ceramic green sheets.

5. The method of fabricating the multilayer ceramic laminate of claim 1, further comprising grinding the surface of the ceramic sintered body after the forming of the ceramic sintered body.

6. A method of fabricating a probe board, comprising:
preparing a ceramic laminate by stacking a plurality of ceramic green sheets including a via through which a conductive material is filled in at least one first through hole;
forming a surface sheet having a buffering electrode connected to the via and provided on the wall surface of a second through hole on the via;
inserting a pillar-type conductor into the second through hole so that one surface thereof is exposed;
forming a ceramic sintered body by firing the ceramic laminate;
forming a connection pad on the ceramic laminate; and
joining a probe part made of conductive material on the ceramic laminate.

7. The method of fabricating the probe board of claim 6, wherein the surface sheet is formed by stacking a plurality of ceramic green sheets.

8. The method of fabricating the probe board of claim 6, further comprising grinding the surface of the ceramic sintered body after the forming of the ceramic sintered body.

9. The method of fabricating the probe board of claim 7, further comprising stacking a protecting layer on the ceramic sintered body after the grinding of the ceramic sintered body.

10. The method of fabricating the probe board of claim 9, wherein the connection pad is formed by forming at least one barrier ribs arranged on the protecting layer at a predetermined interval and filling the inside of the barrier ribs with a metal.

11. The method of fabricating the probe board of claim 10, wherein the connection pad is formed by an electroless plating method.

12. The method of fabricating the probe board of claim 10, wherein, before forming the barrier ribs, a plating seed layer is formed on the protecting layer.

13. The method of fabricating the probe board of claim 12, wherein the connection pad is formed by an electroplating method.

14. The method of fabricating the probe board of claim 10, wherein the probe part is joined by interposing a solder between the plating seed layer and the probe part and removing the protecting layer and the plating seed layer formed on an adhesive pad by melting the solder.

15. A multilayer ceramic substrate, comprising:
a ceramic laminate formed by stacking a plurality of ceramic green sheets including a via through which a conductive material is filled in at least one first through hole;
a surface sheet provided on the via and having a buffering electrode connected to the via and provided on the wall surface of a second through hole; and
a pillar-type conductor inserted into the second through hole so that one surface thereof is exposed.

16. The multilayer ceramic substrate of claim 15, wherein the surface sheet is formed by stacking a plurality of ceramic green sheets.

17. A probe board, comprising:
a ceramic laminate formed by stacking a plurality of ceramic green sheets including a via through which a conductive material is filled in at least one first through hole;
a surface sheet provided on the via and having a buffering electrode connected to the via and provided on the wall surface of a second through hole;
a pillar-type conductor inserted into the second through hole so that one surface thereof is exposed;
a ceramic sintered body formed by firing the ceramic laminate;
a connection pad formed on the ceramic sintered body; and
a probe part joined to the ceramic sintered body and made of a conductive material.

18. The probe board of claim 17, wherein the surface sheet is formed by stacking a plurality of ceramic green sheets.

19. The probe board of claim 17, further comprising a protecting layer on the ceramic sintered body.

20. The probe board of claim 17, wherein the connection pad is formed by an electroless plating method.

21. The probe board of claim 17, wherein the connection pad is formed by an electroplating method.
